(19) United States
(12) Patent Application Publication
(10) Pub. No.: US 2025/0373318 A1
(43) Pub. Date: Dec. 4, 2025

(54) Wi-Fi Booster Sculpture Device

(71) Applicant: Scott Brooks, Montreal (CA)

(72) Inventor: Scott Brooks, Montreal (CA)

(21) Appl. No.: 18/925,791

(22) Filed: Oct. 24, 2024

Related U.S. Application Data
(60) Provisional application No. 63/652,719, filed on May 29, 2024.

(51) Int. Cl. H04B 7/15

(52) U.S. Cl. CPC H04B 7/15

(57) ABSTRACT

A home décor device is disclosed which comprises a body component that is configured in the shape of a home décor such as a fake plant, vase, sculpture, etc. The internet booster is integrated into the base of the device with a longer antenna threaded up to the top of the device. Further, the booster is connected to an outlet by a wire which allows the outlet to be free for more devices to connect to surrounding available outlets as well. The device can be as large or small as is desired, however, larger devices would provide better internet connection because longer antennas can be accommodated within the device. Further, the body component can be any color as is desired by the user and is typically made of a plastic material which allows the Wi-Fi to easily pass through. Thus, the home décor device is functional while beautifying the space.

### CROSS-REFERENCE TO RELATED APPLICATION

The present application claims priority to, and the benefit of, U.S. Provisional Application No. 63/652,719, which was filed on May 29, 2024, and is incorporated herein by reference in its entirety.

### FIELD OF THE INVENTION

The present invention relates generally to the field of home décor devices. More specifically, the present invention relates to a household decoration built around a Wi-Fi booster. Accordingly, the present disclosure makes specific reference thereto. Nonetheless, it is to be appreciated that aspects of the present invention are also equally applicable to other like applications, devices and methods of manufacture.

### BACKGROUND

By way of background, this invention relates to improvements in home décor devices. Generally, people with larger homes may opt to use Wi-Fi boosters, extenders, and repeaters to maintain an optimal internet connection the further they are away from a modem or router. Each device, thus, requires an electrical outlet which can lead to clutter and lack of outlet space for other devices that require it. Accordingly, outlet locations may also not be optimal for maximum signal extension. Further, these extenders and boosters are often unsightly and can take away from the aesthetics of a room or the area of a home.

Accordingly, a piece of home décor constructed in accordance with the invention can be easily plugged into an outlet wherever internet connection is desired. Further, it is often necessary for people to plug multiple devices into outlets inside their home. A traditional Wi-Fi booster would cover up available outlets and make them inaccessible to the user. Accordingly, a booster that plugs into an outlet with a cord would allow the user to use surrounding available outlets for other devices.

Accordingly, there is a demand for an improved home décor device that beautifies wireless internet boosters, extenders, and repeaters. More particularly, there is a demand for a home décor device that does not clutter rooms and outlets with unappealing Wi-Fi boosters.

Therefore, there exists a long felt need in the art for a home décor device that allows home décor items to become functional with internet Wi-Fi booster connectivity while beautifying your space. There is also a long felt need in the art for a home décor device that contains longer antennas for better performance. Further, there is a long felt need in the art for a home décor device that leaves available outlets free from clunky Wi-Fi booster devices. Moreover, there is a long felt need in the art for a device that provides better internet connection for large homes, backyards, commercial spaces, hotels, conference centers, etc. Further, there is a long felt need in the art for a home décor device that provides a fake plant, vase, sculpture, lamp, or other household decoration built around the booster. Finally, there is a long felt need in the art for a home décor device that includes a wire and plug to free up outlet space.

The subject matter disclosed and claimed herein, in one embodiment thereof, comprises a home décor device. The device is a modified Wi-Fi booster built into a piece of home décor. The home décor device comprises a body component that is configured in the shape of a home décor object, such as a fake plant, vase, sculpture, etc. The Wi-Fi booster is integrated into the base of the device with a longer antenna threaded up to the top of the device. Further, the booster is connected to an outlet by a wire and plug which allows the outlet to be free for more devices to connect to surrounding available outlets as well. Thus, the body component takes on the appearance of a piece of home décor, but functions to improve internet connection in the space. The device can be as large or small as is desired, however, larger devices would provide better internet connection because longer antennas can be accommodated within the device. Further, the body component can be any color as is desired by the user and is typically made of a plastic material which allows the Wi-Fi signals to easily pass through. Thus, the home décor device is functional while beautifying the space.

In this manner, the home décor device of the present invention accomplishes all of the forgoing objectives and provides users with a device that provides a Wi-Fi booster that is shaped like an aesthetic piece of home décor. The device is a decorated Wi-Fi booster. The device can comprise a long antennae within it.

### SUMMARY OF THE INVENTION

The following presents a simplified summary in order to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises a home décor device. The device is a modified internet booster, extender, or repeater. The home décor device comprises a body component that can be any kind of home décor object as is desired, such as a fake plant, vase, sculpture, etc. Further, the home décor object is surrounding the internet booster, extender, or repeater so that it looks better within the space. Thus, the body component is large enough to contain the booster and yet small enough to not take up much space. Further, the booster is connected by a wire that plugs into an outlet to allow more outlet space for other necessary devices.

In one embodiment, the home décor device allows users to beautify their space while also gaining better internet connection. Further, the device is empty inside which allows the booster, extender, or repeater to fit within. Accordingly, users can plug the device in away from the outlet to free up available outlet space.

In one embodiment, the home décor comprises a body component that is configured in the base shape of a piece of home décor. This shape could be a fake plant, vase, sculpture, lamp, or other household decoration as is desired. The body component comprises an exterior surface, an interior surface, and an interior space in which the internet connectivity device is fitted within. However, the body component can be any suitable shape and size as is known in the art, as long as the body component is sized and shaped to completely fit an internet connectivity device.

In one embodiment, the body component completely encloses the internet connectivity device which is integrated into the base of the body component. This allows the device to be not only functional but also aesthetic. In this way, the body component must be made of a plastic material or some other material that allows internet waves/signals through.

In one embodiment, the antennas of the internet booster, extender, or repeater could be lengthened when threaded up inside the device. Usually, the antennas are not lengthened for aesthetic purposes or as to not get in the way of normal day-to-day functions. However, when inside the body component, the antennae can be as long as the body component is because it is hidden either way. Thus, with longer antennas, the internet connectivity of the device would have a stronger signal than for devices with smaller antennas.

In one embodiment, the device is plugged into an outlet by a wire attached to the base of the body component. The wire extends from the back side of the exterior surface and plugs into an outlet in the wall. This allows the additional outlets to be freely available. In traditional internet boosters, extenders, or repeaters, the device is always plugged directly into an outlet and covers up the surrounding available outlets. Thus, with a wire/cord plugged into the wall, the surrounding outlets are available for other necessary devices.

In yet another embodiment, the home décor device comprises a plurality of indicia.

In yet another embodiment, a method of beautifying your internet booster is disclosed. The method includes the steps of providing a home décor device comprising a body component with an internet booster. The method also comprises selecting the type of home décor that the body component looks like. Further, the method comprises placing the device in a convenient and productive location. The method also comprises plugging the device into the nearest outlet. Finally, the method comprises turning the device on and ensuring it is working.

Numerous benefits and advantages of this invention will become apparent to those skilled in the art to which it pertains, upon reading and understanding the following detailed specification.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a perspective view of one embodiment of the home décor device of the present invention showing the internet booster in the body component in accordance with the disclosed architecture;

FIG. 2 illustrates a perspective view of one embodiment of the home décor device of the present invention showing a fake plant version of the body component in accordance with the disclosed architecture;

FIG. 3 illustrates a perspective view of one embodiment of the home décor device of the present invention showing a lamp version of the body component in accordance with the disclosed architecture;

FIG. 4 illustrates a perspective view of one embodiment of the home décor device of the present invention showing a decorative object version of the body component in accordance with the disclosed architecture; and

FIG. 5 illustrates a flowchart showing the method of beautifying your internet booster in accordance with the disclosed architecture.

### DETAILED DESCRIPTION OF THE PRESENT INVENTION

The innovation is now described with reference to the drawings, wherein like reference numerals are used to refer to like elements throughout. In the following description, for purposes of explanation, numerous specific details are set forth in order to provide a thorough understanding thereof. It may be evident, however, that the innovation can be practiced without these specific details. In other instances, well-known structures and devices are shown in block diagram form in order to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments may be combined.

As noted above, there is a long felt need in the art for a home décor device that allows home décor items to become functional with internet Wi-Fi booster connectivity while beautifying your space. There is also a long felt need in the art for a home décor device that contains longer antennas for better performance. Further, there is a long felt need in the art for a home décor device that leaves available outlets free from clunky Wi-Fi booster devices. Moreover, there is a long felt need in the art for a device that provides better internet connection for large homes, backyards, commercial spaces, hotels, conference centers, etc. Further, there is a long felt need in the art for a home décor device that provides a fake plant, vase, sculpture, lamp, or other household decoration built around the booster. Finally, there is a long felt need in the art for a home décor device that includes a wire and plug to free up outlet space.

The present invention, in one exemplary embodiment, is a novel home décor device. The home décor device comprises a body component that is configured in the shape of a home décor object, such as a fake plant, vase, sculpture, etc. The Wi-Fi booster is integrated into the base of the device with a longer antenna threaded up to the top of the device. Further, the booster is connected to an outlet by a wire and plug which allows the outlet to be free for more devices to connect to surrounding available outlets as well. Thus, the body component takes on the appearance of a piece of home décor, but functions to improve internet connection in the space. The present invention also includes a novel method of beautifying an internet booster. The method includes the steps of providing a home décor device comprising a body component with an internet booster. The method also comprises selecting the type of home décor object that the body component looks like. Further, the method comprises placing the device in a convenient and productive location. The method also comprises plugging the device into the nearest outlet. Finally, the method comprises turning the device on and ensuring it is working.

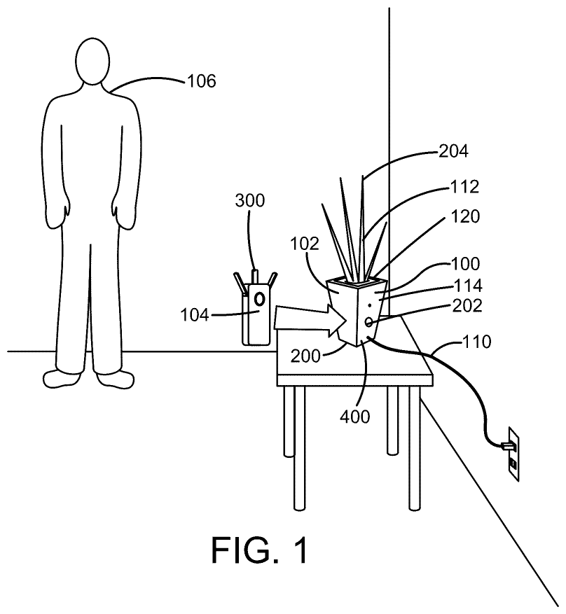

Referring initially to the drawings, FIG. 1 illustrates a perspective view of one embodiment of the home décor device 100 of the present invention. In the present embodiment, the home décor device 100 is an improved home décor device 100 that provides a user 106 with an aesthetically pleasing internet booster. Specifically, the home décor device 100 comprises a body component 102 and an internet booster 104. Thus, the body component 102 is capable of completely concealing the internet booster 104 within it. Further, the internet booster 104 and the body component 102 plug into an outlet 108 through a wire 110.

Generally, the home décor device 100 comprises a body component 102 that is configured in the base shape of a home décor object. This shape could be a fake plant 112, vase 114, sculpture 116, lamp 118, or other household decoration as is desired. The body component 102 comprises an exterior surface 120, an interior surface 122, and an interior space 124 in which the internet booster 104 is fitted within. However, the body component 102 can be any suitable shape and size as is known in the art, as long as the body component 102 is sized and shaped to completely encase an internet booster 104.

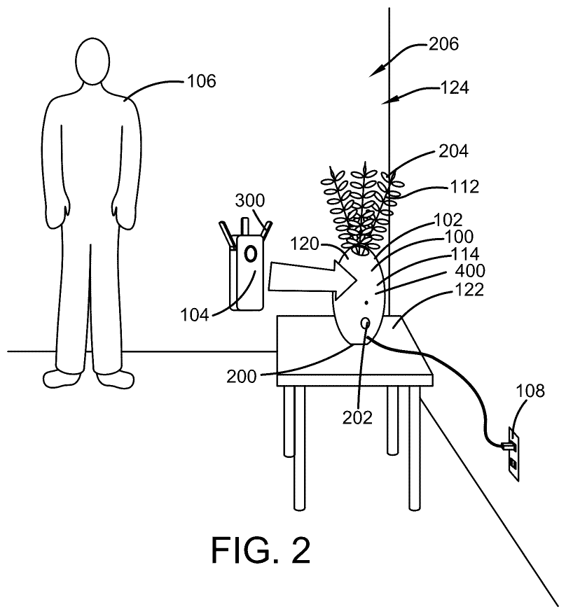

As shown in FIG. 2, the internet booster 104 is encased inside the body component 102. In this way, the internet booster 104 is integrated into the base 200 of the body component. Thus, the base 200 shows the light 202 that is typically on an internet booster 104 to indicate that the internet booster 104 is on. Thus, the home décor device 100 functions as a traditional internet booster, and yet is perceived as a piece of home décor. This allows the device 100 to be not only functional but also aesthetic.

Accordingly, the body component 102 is typically made of a plastic material 204 or some other material 204 that allows internet waves/signals through as the internet booster 104 is placed within the body component 102 and is able to further extend its reach throughout a room 206.

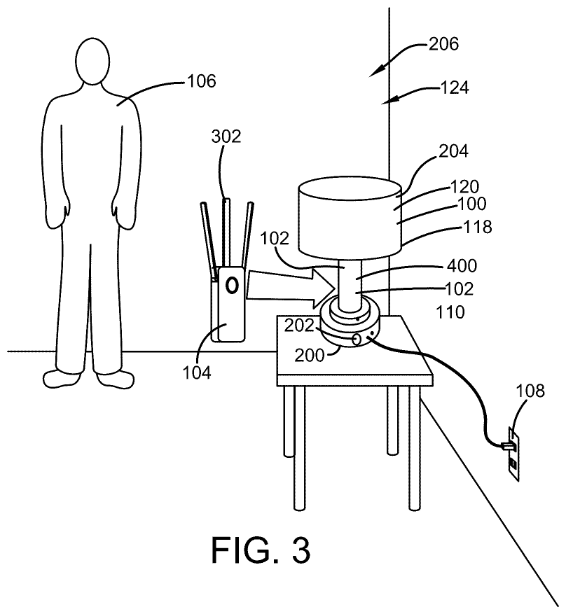

As shown in FIG. 3, the antennas 300 of the internet booster 104 could be lengthened when threaded up inside the body component 102. Traditionally, the antennas 300 are not lengthened for aesthetic purposes or as to not get in the way of normal day-to-day functions. However, when inside the body component 102, the antennae 300 can be as long as the body component 102 is, because it is hidden either way. Thus, with longer antennas 302, the internet connectivity of the device 100 would be stronger than with traditional antennas 300.

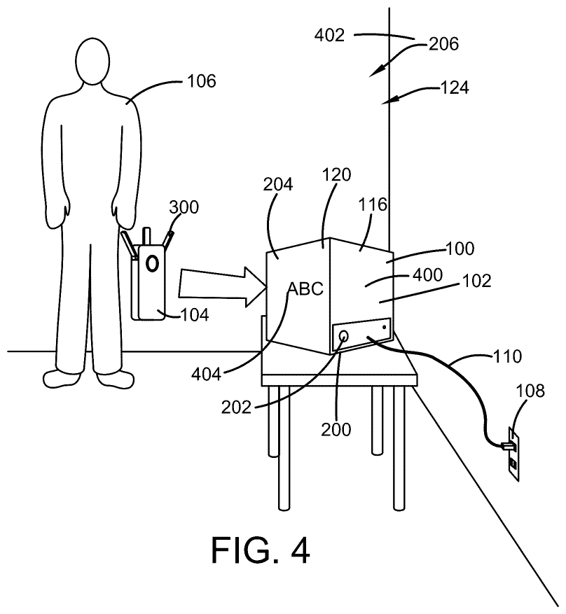

As shown in FIG. 4, the device 100 is plugged into an outlet 108 by a wire/cord 110 attached to the base 200 of the body component 102. The wire 110 extends from the back side 400 of the exterior surface 120 and plugs into an outlet 180 in the wall 402. This allows the additional outlets 180 around the one being used by the device 100 to be freely available. In traditional internet boosters 104, the device 100 is always plugged directly into an outlet 108 and covers up the surrounding available outlets 108. Thus, with a wire 110 plugged into the wall 402, the surrounding outlets 108 are available for other necessary devices.

In another embodiment, the home décor device 100 can be plugged directly into the outlet 108 without the use of a wire/cable 110 to resemble a more traditional internet booster 104. This would cover up more available outlets 108 but would also reduce the amount of wires 110 in the area.

In yet another embodiment, the home décor device 100 comprises a plurality of indicia 404. The body component 102 of the device 100 may include advertising, a trademark, or other letters, designs, or characters, printed, painted, stamped, or integrated into the body component 102, or any other indicia 404 as is known in the art. Specifically, any suitable indicia 404 as is known in the art can be included, such as but not limited to, patterns, logos, emblems, images, symbols, designs, letters, words, characters, animals, advertisements, brands, etc., that may or may not be Wi-Fi, home décor, or brand related.

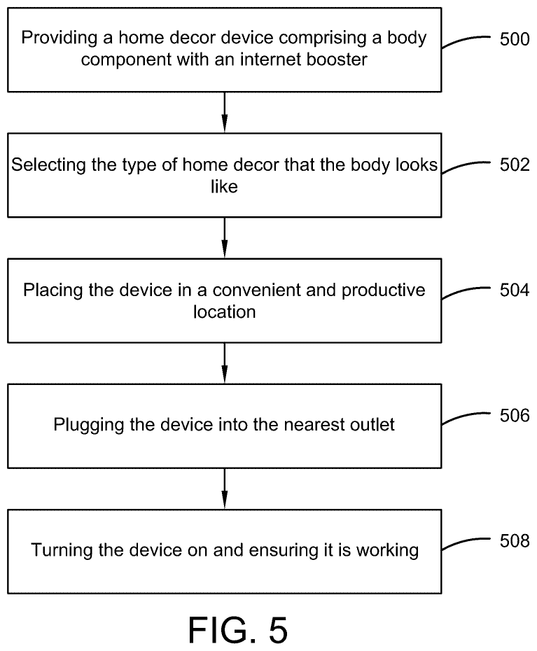

FIG. 5 illustrates a flowchart of the method beautifying an internet booster. The method includes the steps of at 500, providing a home décor device comprising a body component with an internet booster. The method also comprises at 502, selecting the type of home décor that the body component looks like. Further, the method comprises at 504, placing the device in a convenient and productive location. The method also comprises at 506, plugging the device into the nearest outlet. Finally, the method comprises at 508, turning the device on and ensuring it is working.

Certain terms are used throughout the following description and claims to refer to particular features or components. As one skilled in the art will appreciate, different users may refer to the same feature or component by different names. This document does not intend to distinguish between components or features that differ in name but not structure or function. As used herein “home décor device”, “internet booster device”, “décor device”, and “device” are interchangeable and refer to the home décor device 100 of the present invention.

Notwithstanding the forgoing, the home décor device 100 of the present invention can be of any suitable size and configuration as is known in the art without affecting the overall concept of the invention, provided that it accomplishes the above stated objectives. One of ordinary skill in the art will appreciate that the home décor device 100 as shown in FIGS. 1-5 is for illustrative purposes only, and that many other sizes and shapes of the home décor device 100 are well within the scope of the present disclosure. Although the dimensions of the home décor device 100 are important design parameters for user convenience, the home décor device 100 may be of any size that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A home décor device that provides a user with an aesthetically pleasing internet booster, the home décor device comprising:
a body component; and
internet booster;
wherein the internet booster is encased within the body component; and
further wherein the internet booster is integrated into a bottom of the body component.

2. The home décor device of claim 1, wherein the body component is configured in shape of a traditional piece of home décor which includes but is not limited to, a fake plant, vase, or sculpture.

3. The home décor device of claim 2, wherein the body component comprises an exterior surface, an interior surface, and an interior space where the internet booster is enclosed.

4. The home décor device of claim 3, wherein the interior surface of the body component is hollow and allows the internet booster to extend longer antennas than traditionally used which picks up on more internet connectivity.

5. The home décor device of claim 4, wherein the body component is plugged into an outlet in a wall via a wire which allows for available outlets to not be blocked.

6. The home décor device of claim 4, wherein the body component can also plug in directly to the wall to allow less wire clutter.

7. The home décor device of claim 5, wherein the base of the body component illuminates light that is traditionally on an internet booster and which allows a user to know whether the home décor device is on or off.

8. The home décor device of claim 6, wherein the body component is comprised of a plastic material which allows internet signals to pass through in order for internet connectivity not to be blocked by the body component.

9. The home décor device of claim 8, wherein the body component is sized and shaped to accommodate an internet booster fitting within the body component.

10. The home décor device of claim 9, wherein the body component is available in a variety of colors.

11. The home décor device of claim 10, wherein the home décor device can be placed in any position in a room which will best allow for transmission of internet connectivity.

12. The home décor device of claim 11 further comprising a plurality of indicia.

13. A home décor device that provides a user with an aesthetically pleasing internet booster, the home décor device comprising:
a body component configured in a shape of a traditional piece of home décor; and
an internet booster;
wherein the body component comprises an exterior surface, an interior surface, and an interior space;
wherein the internet booster is encased inside the interior space;
wherein the home décor device is placed strategically within a room to allow for most internet connectivity; and
further wherein the internet booster is integrated into the base of the body component.

14. The home décor device of claim 13 further comprising a plurality of indicia.

15. The home décor device of claim 13, wherein the base of the body component comprises a light to indicate to users whether the home décor device is on or off.

16. The home décor device of claim 15, wherein the body component is plugged into an outlet in a wall through a wire which frees up available outlets to be used.

17. The home décor device of claim 16, wherein the internet booster's antenna extends within the interior space of the body component.

18. The home décor device of claim 17, wherein the body component is comprised of a plastic material which best allows electromagnetic waves to pass through in order to provide internet connectivity.

19. The home décor device of claim 18, wherein the body component is available in a variety of shapes and designs to match aesthetics of a room.

20. A method of beautifying an internet booster, the method comprising the following steps:
providing a home décor device comprising a body component with an internet booster;
selecting type of home décor that the body component looks like;
placing the home décor device in a convenient and productive location;
plugging the home décor device into the nearest outlet; and
turning the home décor device on and ensuring it is working.
